(19) United States
(12) Patent Application Publication
(10) Pub. No.: US 2010/0284210 A1
(43) Pub. Date: Nov. 11, 2010

(54) One-time programmable memory cell

(75) Inventors: Henry Kuo-Shun Chen, Irvine, CA (US); Xiangdong Chen, Irvine, CA (US); Wei Xia, Irvine, CA (US)

Correspondence Address: FARJAMI & FARJAMI LLP, 26522 LA ALAMEDA AVENUE, SUITE 360, MISSION VIEJO, CA, 92691, US

(73) Assignee: BROADCOM CORPORATION, Irvine, CA (US)

(21) Appl. No.: 12/387,573

(22) Filed: May 5, 2009

(51) Int. Cl. G11C 17/00

(52) U.S. Cl. 365/104; 365/94

(57) ABSTRACT

According to one exemplary embodiment, a one-time programmable memory cell includes an access transistor coupled to a cell transistor between a bitline and a ground, where the access transistor has a gate coupled to a wordline. The cell transistor has a source, a gate, and a body shorted together. A programming operation causes a punchthrough to occur between the source and a drain of the cell transistor in response to a programming voltage on the bitline and the wordline. A channel length of the cell transistor is substantially less than a channel length of the access transistor. In one embodiment, the access transistor is an NFET while the cell transistor is a PFET. In another embodiment, the access transistor is an NFET and the cell transistor is also an NFET. Various embodiments result in a reduction of the required programming voltage.

### BACKGROUND OF THE INVENTION

1. Field of the Invention

The present invention is generally in the field of semiconductors. More particularly, the invention is in the field of semiconductor memory cells.

2. Background Art

One-time programmable memory cells, which can be programmed only once, can be generally utilized in any integrated circuit (IC) chip for storing information that is to be retained when the memory cells are no longer supplied with power. For example, one-time programmable memory cells can be utilized for storing information related to device identification, characteristics, and fabrication processes. A one-time programmable memory cell is typically programmed in a programming operation that irreversibly alters the structure of the memory cell.

A conventional one-time programmable memory cell can include a transistor including a gate oxide disposed between a gate and a substrate, which forms a body of the transistor, and a source and a drain, which are situated in the substrate adjacent to the gate. During a programming operation, a programming voltage can be applied to the gate to cause the gate oxide to break down, thereby programming the memory cell by irreversibly changing the gate oxide from an insulator to a conductor. To break down the gate oxide, a programming voltage of at least 6.0 volts can be required, which can, in turn, require a charge pump and associated circuitry. However, the charge pump and the associated circuitry for providing the necessary programming voltage for the conventional one-time programmable memory cell can undesirably increase power consumption, complexity, and cost.

### SUMMARY OF THE INVENTION

A one-time programmable memory cell with cell transistor subject to punchthrough is provided. Features, advantages and various embodiments of the present invention are shown in and/or described in connection with at least one of the drawings, as set forth more completely in the claims.

### BRIEF DESCRIPTION OF THE DRAWINGS

FIG. 1 illustrates a circuit diagram of an exemplary one-time programmable memory cell in accordance with one embodiment of the present invention.

FIG. 2 illustrates a circuit diagram of an exemplary one-time programmable memory cell in accordance with another embodiment of the present invention.

FIG. 3 is a graph showing an exemplary leakage current curve of an exemplary one-time programmable memory cell in accordance with one embodiment of the present invention.

FIG. 4 shows a flowchart illustrating an exemplary method for programming an exemplary one-time programmable memory cell in accordance with one embodiment of the present invention.

### DETAILED DESCRIPTION OF THE INVENTION

The present invention is directed to a one-time programmable memory cell with cell transistor subject to punchthrough. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings.

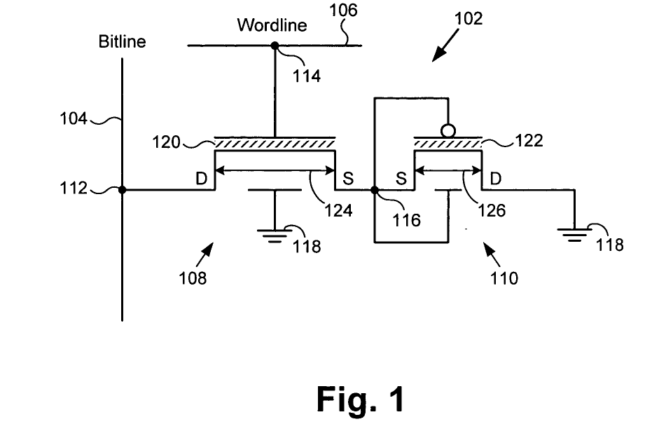

FIG. 1 shows a circuit diagram of an exemplary one-time programmable memory cell in accordance with one embodiment of the present invention. In FIG. 1, one-time programmable memory cell 102 (hereinafter referred to simply as “memory cell 102” in the present application) is coupled to bitline 104 and wordline 106 and includes access transistor 108 and cell transistor 110. Memory cell 102 can be generally utilized in any semiconductor die or IC chip for storing information. For example, memory cell 102 can be utilized to store information related to device identification, characteristics, and fabrication processes, and the like. Memory cell 102 can be utilized in a memory array (not shown in FIG. 1), which can include a number of one-time programmable memory cells, such as memory cell 102, as well as a number of bitlines and wordlines, such as bitline 104 and wordline 106.

As shown in FIG. 1, the drain of access transistor 108 is coupled to bitline 104 at node 112, the gate of access transistor 108 is coupled to wordline 106 at node 114, and the source of access transistor 108 is coupled to the gate, the source, and the body of cell transistor 110 at node 116. In the embodiment of the invention shown in FIG. 1, access transistor 108 can be an N channel field effect transistor (NFET). In one embodiment of the invention, access transistor 108 can be a P channel FET (PFET). In the embodiment in FIG. 1, cell transistor 110 can be a PFET. In one embodiment of the invention, cell transistor 110 can be an NFET. Also shown in FIG. 1, the body of access transistor 108 and the drain of cell transistor 110 are coupled to ground 118.

Further shown in FIG. 1, access transistor 108 includes gate dielectric 120, which underlies the gate and overlies the channel of access transistor 108. Also shown in FIG. 1, cell transistor 110 includes gate dielectric 122, which underlies the gate and overlies the channel of cell transistor 110. Gate dielectrics 120 and 122 can each comprise, for example, silicon oxide or other suitable gate insulating material. Gate dielectrics 120 and 122 can each have a thickness greater than, for example, approximately 50.0 Angstroms. Further shown in FIG. 1, access transistor 108 has channel length 124 and cell transistor 110 has channel length 126. Channel length 126 of cell transistor 110 is significantly less than channel length 124 of access transistor 108. Channel length 126 of cell transistor 110 can be, for example, between approximately 0.25 microns and approximately 0.40 microns in an embodiment of the invention. In one embodiment, channel length 126 of cell transistor 110 can be less than 0.25 microns.

Memory cell 102 can store a bit of data in cell transistor 110 and can have a logic state of “0” or “1”. Memory cell 102 can be programmed in a programming operation by applying a sufficiently high programming voltage to bitline 104 and wordline 106 so as cause “punchthrough” to occur between the source and drain of cell transistor 110, where “punchthrough” refers to a breakdown mechanism caused by an overlap between source and drain depletion regions. As a result of punchthrough, permanent damage can occur between the source and drain of cell transistor 110, which significantly increases source-to-drain leakage current. Thus, current conduction from source to drain of cell transistor 110 is substantially increased after the programming operation compared to source-to-drain current conduction of cell transistor 110 prior to programming.

In an embodiment in which cell transistor 110 is a PFET, a “punchthrough voltage” can be defined as the minimum source-to-drain voltage that is required to cause punchthrough in cell transistor 110. Since the drain of cell transistor 110 is coupled to ground, the punchthrough voltage can represent the minimum voltage at node 116 that is required to cause punchthrough. In an embodiment in which cell transistor 110 is an NFET, the punchthrough voltage can be defined as the minimum drain-to-source voltage that is required to cause punchthrough. The punchthrough voltage is dependent on the channel length (i.e. channel length 126) of the cell transistor. For example, a decrease in channel length can reduce the punchthrough voltage, while an increase in channel length can increase the punchthrough voltage. The punchthrough voltage can be provided at node 116 by applying a sufficiently high programming voltage to bitline 104 and wordline 106.

In an embodiment of the invention, a programming voltage of approximately 5.0 volts can be applied to bitline 104 and wordline 106 during a programming operation. As a result of a small gate-to-source voltage (V_{GS}) drop in access transistor 108, a programming voltage of approximately 4.4 volts can be applied at the source of access transistor 108, which can be sufficient to cause punchthrough between the source and drain of cell transistor 110 for a channel length (i.e. channel length 126) of approximately 0.25 microns or less. In one embodiment, the punchthrough voltage can be between approximately 3.0 volts and approximately 7.0 volts and the corresponding channel length of cell transistor 110 can be less than approximately 0.4 microns. In a programming operation, memory cell 102 can be programmed by applying a programming voltage to bitline 104 and wordline 106 so as to cause a punchthrough to occur between the source and drain of cell transistor 110, thereby substantially increasing the leakage current of cell transistor 110. Prior to programming and after programming, V_{GS} of cell transistor 110 can be substantially equal to 0.0 volts. As a result of the programming operation, the leakage current of cell transistor 110 is substantially increased compared to its leakage current prior to programming operation. In one embodiment, the leakage current of cell transistor 110 can be increased by, for example, approximately five orders of magnitude as a result of the punchthrough that occurs during programming of memory cell 102. The low leakage current of cell transistor 110 prior to punchthrough can be utilized to define a logic “0” state of memory cell 102 and the high leakage current of cell transistor 110 after punchthrough can be utilized to define a logic “1” state of memory cell 102, or vice versa.

To perform a read operation on memory cell 102, a supply voltage (i.e. Vdd) can be applied to bitline 104 and wordline 106, where the supply voltage can be, for example, less than approximately 3.3 volts. If memory cell 102 has been programmed, a high sensing current corresponding to the high leakage current of cell transistor 110 can be detected on bitline 104 during the read operation.

By utilizing cell transistor 110, an embodiment of the invention's memory cell 102 can achieve a low programming voltage and a high sensing current. The punchthrough voltage of memory cell 102 can be adjusted by appropriately adjusting the cell transistor's channel length. As a result, an embodiment of the invention's memory cell 102 can require a lower programming voltage compared to a conventional one-time programmable memory cell that is programmed via gate oxide breakdown. Also, the conventional one-time programmable memory cell can require a charge pump and associated circuitry, which undesirably increases power consumption. In contrast, an embodiment of the invention's memory cell 102 can be advantageously programmed without requiring a charge pump and associated circuitry, thereby advantageously reducing power consumption compared to the conventional one-time programmable memory cell.

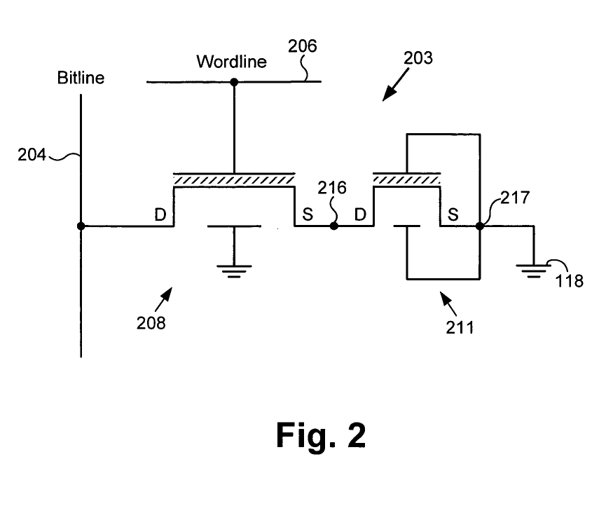

FIG. 2 shows a circuit diagram of an exemplary one-time programmable memory cell in accordance with another embodiment of the present invention. In FIG. 2, one-time programmable memory cell 203 (hereinafter referred to simply as “memory cell 203” in the present application) is coupled to bitline 204 and wordline 206 and includes access transistor 208 and cell transistor 211. In FIG. 2, bitline 204, wordline 206, access transistor 208 and ground 218 correspond, respectively, to bitline 104, wordline 106, access transistor 108 and ground 118 in FIG. 1. In contrast to cell transistor 110 in memory cell 102 in FIG. 1, cell transistor 211 comprises an NFET. Thus, in memory cell 203, both access transistor 218 and cell transistor 211 can comprise NFETs. However, the channel length of cell transistor 211 is significantly less than the channel length of access transistor 218.

As shown in FIG. 2, the source of access transistor 208 is coupled to the drain of cell transistor 211 at node 216 and the source, gate, and body of cell transistor 211 are coupled to ground 218 at node 217. In memory cell 203, a substantially similar punchthrough voltage as discussed above for memory cell 102 can be applied to the drain of cell transistor 211 at node 216 to cause a punchthrough to occur between the drain and source of cell transistor 211. Memory cell 203 provides similar advantageous as discussed above in relation to memory cell 102.

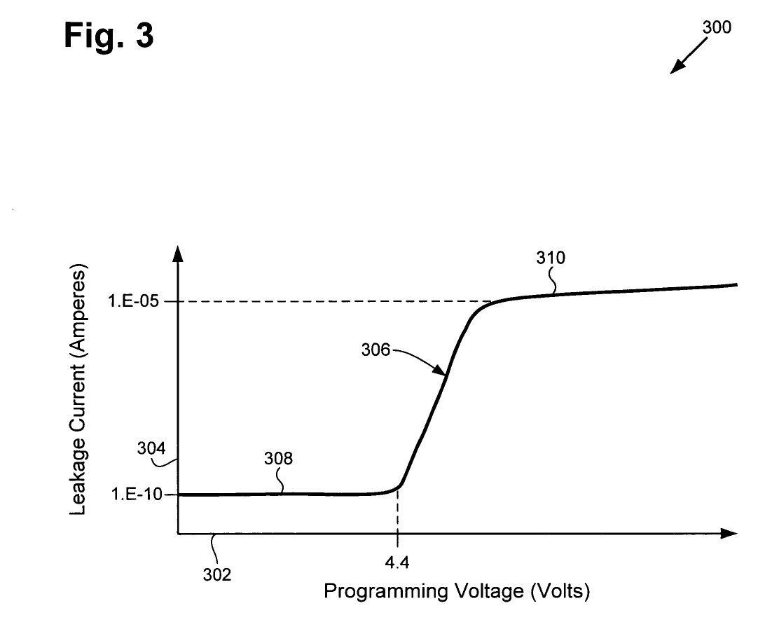

FIG. 3 shows exemplary graph 300 including an exemplary sensing current curve of an exemplary one-time programmable memory cell in accordance with one embodiment of the present invention. Graph 300 includes programming voltage axis 302, leakage current axis 304, and leakage current curve 306. In graph 300, programming voltage axis 302 corresponds to an exemplary programming voltage applied to cell transistor 110 in FIG. 1 at node 116 during a programming operation and leakage current axis 304 corresponds to an exemplary range of leakage current of cell transistor 110. In graph 300, leakage current curve 306 corresponds to the leakage current of cell transistor 110 with respect to programming voltage at node 116 in FIG. 1. The leakage current of cell transistor 110 corresponds to a sensing current, which can be detected on bitline 104 in FIG. 1 during a read operation of memory cell 102.

In the example shown in graph 300, V_{GS} of cell transistor 110 can be substantially equal to 0.0 volts prior to programming and after programming and channel length 126 of cell transistor 110 can be equal to approximately 0.25 microns or less. Also, in the example shown in graph 300, punchthrough can occur in cell transistor 110 at a programming voltage equal to approximately 4.4 volts. To achieve a punchthrough at programming voltage of approximately 4.4 volts at node 116, a programming voltage of approximately 5.0 volts can be applied to bitline 104 and wordline 106 in FIG. 1.

As shown in the example in graph 300, cell transistor 110 has a leakage current equal to approximately 1.E-10 amperes prior to punchthrough (i.e. prior to programming), which is indicated by portion 308 of leakage current curve 306), and has a leakage current equal to approximately 1.E-05 amperes after punchthrough (i.e. after programming), which is indicated by portion 310 of leakage current curve 306. Thus, as a result of punchthrough, the leakage current of cell transistor 110 can be increased by, for example, approximately five orders of magnitude. In the example shown in graph 300, the leakage current of cell transistor 110 after programming (i.e. after punchthrough) can be measured on bitline 104 in FIG. 1 by applying a voltage (i.e. Vdd) equal to approximately 2.5 volts to bitline 102 and wordline 106. The low leakage current of cell transistor 110 can be utilized to define a logic “0” state of memory cell 102 and the high leakage current of the cell transistor after punchthrough can be utilized to define a logic “1” state of memory cell 102, or vice versa.

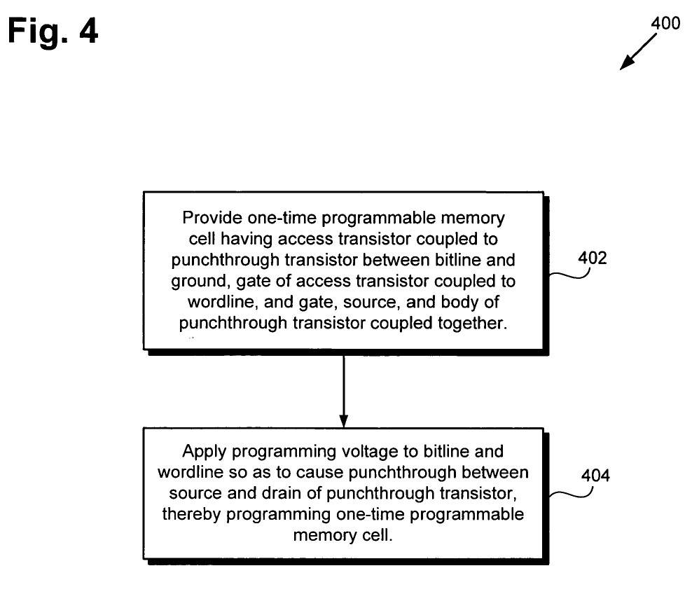

FIG. 4 shows a flowchart illustrating an exemplary method for programming a one-time programmable memory cell according to one embodiment of the present invention. Certain details and features have been left out of flowchart 400 that are apparent to a person of ordinary skill in the art. For example, a step may consist of one or more substeps or may involve specialized equipment, as known in the art.

At step 402 of flowchart 400, a one-time programmable memory cell (e.g. memory cell 102 in FIG. 1) can be provided having an access transistor (e.g. access transistor 108) coupled to a cell transistor (e.g. cell transistor 110) between a bitline (e.g. bitline 104) and ground (e.g. ground 118), the gate of the access transistor coupled to the wordline, and the gate, source, and body of the cell transistor coupled together. In the embodiment in FIG. 1, access transistor 108 can be an NFET and cell transistor 110 can be a PFET. In the embodiment in FIG. 2, access transistor 208, which can be an NFET, can be coupled to cell transistor 211, which can be a PFET, between bitline 204 and ground 218, and the gate, source, and body of cell transistor 211 can be coupled to ground 218 at node 217.

At step 404 of flowchart 400, a programming voltage can be applied to the bitline (e.g. bitline 104) and the wordline (e.g. wordline 106) so as to cause punchthrough between the source and drain of the cell transistor (e.g. cell transistor 110), thereby programming the one-time programmable memory cell (e.g. memory cell 102). By causing punchthrough between the source and drain of the cell transistor, the cell transistor can be permanently damaged, thereby substantially increasing its leakage current. The punchthrough voltage that is applied at node 116 to cause punchthrough to occur in cell transistor 110 is related to the channel length (e.g. channel length 126) of the cell transistor. In an embodiment of the invention, the punchthrough voltage can be between approximately 4.0 volts and approximately 8.0 volts and the corresponding channel length can be between approximately 0.2 microns and approximately 0.3 microns.

Thus, as discussed above, the present invention provides a one-time programmable memory cell including an access transistor coupled to a cell transistor. The invention's one-time programmable memory cell can be programmed by causing a punchthrough to occur between the source and drain of the cell transistor, which substantially increasing the leakage current of the cell transistor. As a result, an embodiment of the invention's one-time programmable memory cell can require a lower programming voltage compared to a conventional one-time programmable memory cell that is programmed by other techniques, such as by gate oxide breakdown.

Also, the conventional one-time programmable memory cell can require a charge pump and associated circuitry to provide the necessary programming voltage. In contrast, an embodiment of the invention's one-time programmable memory cell can be programmed without requiring a charge pump and associated circuitry, thereby advantageously reducing power consumption, complexity, and cost compared to the conventional one-time programmable memory cell.

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

1. A one-time programmable memory cell comprising:
an access transistor coupled between a bitline and a cell transistor, said access transistor having a gate coupled to a wordline;
said cell transistor being coupled between said access transistor and a ground, said cell transistor having a source, a gate, and a body shorted together;
wherein a punchthrough occurs between said source and a drain of said cell transistor in response to a programming voltage on said bitline and said wordline.

2. The one-time programmable memory cell of claim 1, wherein a channel length of said cell transistor is substantially less than a channel length of said access transistor.

3. The one-time programmable memory cell of claim 1, wherein said cell transistor is a PFET having said drain coupled to said ground.

4. The one-time programmable memory cell of claim 1, wherein said cell transistor is an NFET having said drain coupled to said access transistor and said source, said body, and said gate coupled to said ground.

5. The one-time programmable memory cell of claim 1, wherein said punchthrough causes a leakage current to substantially increase between said source and said drain of said cell transistor, thereby programming said memory cell.

6. The one-time programmable memory cell of claim 1, wherein a channel length of said cell transistor is less than approximately 0.4 microns.

7. The one-time programmable memory cell of claim 1, wherein said programming voltage is between approximately 3.0 volts and approximately 7.0 volts.

8. A method for programming a one-time programmable memory cell, said one-time programmable memory cell comprising an access transistor coupled between a bitline and a cell transistor, said access transistor having a gate coupled to a wordline, said cell transistor being coupled between said access transistor and a ground, said cell transistor having a source, a gate, and a body shorted together, said method comprising:
applying a programming voltage to said bitline and said wordline so as to cause a punchthrough to occur between a source and a drain of said cell transistor, thereby substantially increasing a leakage current in said cell transistor so as to result in programming said one-time programmable memory cell.

9. The method of claim 8, wherein a channel length of said cell transistor is substantially less than a channel length of said access transistor.

10. The method of claim 8, wherein said cell transistor is a PFET having said drain coupled to said ground.

11. The method of claim 8, wherein said cell transistor is an NFET having said drain coupled to said access transistor and said source, said body, and said gate coupled to said ground.

12. The method of claim 8, wherein said access transistor is an NFET having a drain coupled to said bitline and a source coupled to said cell transistor.

13. The method of claim 8, wherein a channel length of said cell transistor is less than approximately 0.4 microns.

14. The method of claim 8, wherein said programming voltage is between approximately 3.0 volts and approximately 7.0 volts.

15. A one-time programmable memory cell comprising:
an NFET access transistor coupled to a cell transistor between a bitline and a ground, said access transistor having a gate coupled to a wordline, a drain coupled to said bitline, and a source coupled to said cell transistor;
said cell transistor having a source, a gate, and a body shorted together;
wherein a programming operation causes a punchthrough to occur between said source and a drain of said cell transistor in response to a programming voltage on said bitline and said wordline.

16. The one-time programmable memory cell of claim 15, wherein a channel length of said cell transistor is substantially less than a channel length of said access transistor.

17. The one-time programmable memory cell of claim 15, wherein said cell transistor is a PFET.

18. The one-time programmable memory cell of claim 15, wherein said drain of said cell transistor is coupled to said access transistor.

19. The one-time programmable memory cell of claim 15, wherein a channel length of said cell transistor is less than approximately 0.4 microns.

20. The one-time programmable memory cell of claim 15, wherein said programming voltage is between approximately 3.0 volts and approximately 7.0 volts.
